(19) United States
(12) Patent Application Publication
(10) Pub. No.: US 2012/0074466 A1
(43) Pub. Date: Mar. 29, 2012

(54) 3D MEMORY ARRAY WITH VERTICAL TRANSISTOR

(75) Inventors: Dadi Setiadi, Edina, MN (US); Peter Nicholas Manos, Eden Prairie, MN (US); Hsing-Kuen Liou, Plymouth, MN (US); Paramasivan Kamatchi Subramanian, Edina, MN (US); Young Pil Kim, Eden Prairie, MN (US); Hyung-Kyu Lee, Edina, MN (US); Maroun Georges Khoury, Burnsville, MN (US); Chulmin Jung, Eden Prairie, MN (US)

(73) Assignee: SEAGATE TECHNOLOGY LLC, Scotts Valley, CA (US)

(21) Appl. No.: 12/891,982

(22) Filed: Sep. 28, 2010

(51) Int. Cl. H01L 27/088; H01L 21/8239

(52) U.S. Cl. 257/204; 438/128; 257/E27.06; 257/E21.645

(57) ABSTRACT

A memory array includes a base circuitry layer and a plurality of memory array layers stacked sequentially to form the memory array. Each memory array layer is electrically coupled to the base circuitry layer. Each memory array layer includes a plurality of memory units. Each memory unit includes a vertical pillar transistor electrically coupled to a memory cell.

### BACKGROUND

Solid state memories (SSMs) provide an efficient mechanism for storing and transferring data in a wide variety of applications, such as hand-held portable electronic devices. Individual memory cells within such memories can be volatile or non-volatile, and can store data by the application of suitable write currents to the cells to store a sequence of bits. The stored bits can be subsequently read during a read access operation by applying suitable read currents and sensing voltage drops across the cells.

Some SSM cell configurations employ a memory element coupled to a channel based switching device such as a metal oxide semiconductor field effect transistor (MOSFET). The switching device provides selective access to the memory element during read and write operations. Examples of memory cells with this type of memory element-switching device arrangement include, but are not limited to, volatile dynamic random access memory (DRAM), non-volatile resistive random access memory (RRAM), and non-volatile spin-torque transfer random access memory (STRAM).

While operable, a limitation with the use of MOSFETs and other types of switching devices in a memory cell is the areal extent (size) of such devices. A horizontal MOSFET layout is often used in which the associated drain and source regions are placed adjacent one another in a base substrate, with the channel region extending horizontally therebetween. The memory element is formed above either the source or the drain.

Horizontal MOSFETs may require a minimum size of about 4F² where F is the minimum feature dimension of the associated manufacturing process (e.g., F=70 nm, etc.). Since this is significantly larger than the areal size of many types of memory elements, the switching device size can be a limiting factor in achieving greater areal densities in a memory array.

Some recent semiconductor memory designs have proposed a stacked memory cell arrangement whereby the memory element and the transistor are vertically aligned as a pillar, or stack, above a base substrate. In a stacked memory cell, the drain and source regions are located one above the other, with the channel region extending vertically therebetween. While advantageously promoting an enhanced areal data density, it can be difficult to form the pillar structure of the vertical transistor so that the transistor can operate optimally.

### BRIEF SUMMARY

The present disclosure relates to a memory array that includes a plurality of memory array layers that are stacked on a base circuitry layer and individually controlled by the single base circuitry layer. In particular, the memory array that includes a plurality of memory array layers that includes a plurality of memory units where each memory unit includes a vertical pillar transistor electrically coupled to a STRAM or RRAM memory cell. The resulting 3D stacked memory array is a high density and high fill factor memory device.

In one particular embodiment, a memory array includes a base circuitry layer and a plurality of memory array layers stacked sequentially to form the memory array. Each memory array layer is electrically coupled to the base circuitry layer. Each memory array layer includes a plurality of memory units. Each memory unit includes a vertical pillar transistor electrically coupled to a memory cell.

In another particular embodiment, a method of forming a memory array includes forming a first memory array layer on a base circuitry layer and the first memory array layer is electrically coupled to the base circuitry layer. The first memory array layer includes a plurality of memory units including a vertical pillar transistor electrically coupled to a memory cell. Then a semiconductor layer is disposed on the first memory array layer. A second memory array layer is formed from the semiconductor layer. The second memory array layer is electrically coupled to the base circuitry layer. The second memory array layer includes a plurality of memory units including a vertical pillar transistor electrically coupled to a memory cell.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 shows a functional block representation of an exemplary data storage device constructed in accordance with various embodiments of the present invention;

FIG. 2 is a schematic representation of a memory array of the device of FIG. 1;

FIG. 3 is a side elevational representation of various semiconductor layers of a vertically stacked memory cell of FIG. 2 in accordance with some embodiments;

FIGS. 4A-4B show prior art approaches to establishing bottom side interconnection to vertically stacked memory cells such as set forth in FIG. 3;

FIG. 5A shows an acceptor wafer constructed in accordance with some embodiments;

FIG. 5B shows a donor wafer constructed in accordance with some embodiments;

FIG. 6 shows a multi-wafer structure formed by attachment of respective conductive layers of the acceptor and donor wafers of FIGS. 5A-5B to form a combined conductive wafer embedded within the multi-wafer structure;

FIGS. 7A-7B provide respective side elevational and top plan views of the structure of FIG. 6 to which dots of photoresist (PR) material have been applied;

FIG. 8 represents application of an etching process to the structure of FIGS. 7A-7B to form a plurality of spaced apart stacked pillars of semiconductor material arranged into rows and columns;

FIGS. 9A-9B illustrate respective side elevation and top plan views of the application of masking material to form embedded control lines from the combined conductive layer within the structure;

FIG. 10 shows an elevational view of the resulting plurality of embedded control lines formed using the masking material of FIGS. 9A-9B;

FIG. 10A illustrates a side elevation view of a hardening implantation step;

FIG. 10B illustrates a side elevation view of a sacrificial oxide formation step;

FIG. 10C illustrates a side elevation view of a selective oxide etch step;

FIG. 10D illustrates a side elevation view of a gate oxide formation step;

FIGS. 11A-11D show a sequence in which gate structures are formed;

FIGS. 12A-12B illustrate subsequent formation of spaced apart bit lines across the top side of the pillars of semiconductor material;

FIGS. 13A-13B provide an alternative configuration for the multi-wafer structure in accordance with various embodiments;

FIG. 14 is an exploded perspective schematic diagram of an illustrative 3D memory array; and

FIG. 15A to FIG. 15C are schematic diagram side elevation views of method of forming an illustrative 3D memory array.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “lower”, “upper”, “beneath”, “below”, “above”, and “on top”, if used herein, are utilized for ease of description to describe spatial relationships of an element(s) to another. Such spatially related terms encompass different orientations of the device in use or operation in addition to the particular orientations depicted in the figures and described herein. For example, if a cell depicted in the figures is turned over or flipped over, portions previously described as below or beneath other elements would then be above those other elements.

As used herein, when an element, component or layer for example is described as forming a “coincident interface” with, or being “on” “connected to”, “coupled with” or “in contact with” another element, component or layer, it can be directly on, directly connected to, directly coupled with, in direct contact with, or intervening elements, components or layers may be on, connected, coupled or in contact with the particular element, component or layer, for example. When an element, component or layer for example is referred to as begin “directly on”, “directly connected to”, “directly coupled with”, or “directly in contact with” another element, there are no intervening elements, components or layers for example.

The present disclosure relates to a memory array that includes a plurality of memory array layers that are stacked on a base circuitry layer and individually controlled by the single base circuitry layer. In particular, the memory array that includes a plurality of memory array layers that includes a plurality of memory units where each memory unit includes a vertical pillar transistor electrically coupled to a STRAM or RRAM memory cell. The resulting 3D stacked memory array is a high density and high fill factor memory device. While the present disclosure is not so limited, an appreciation of various aspects of the disclosure will be gained through a discussion of the examples provided below.

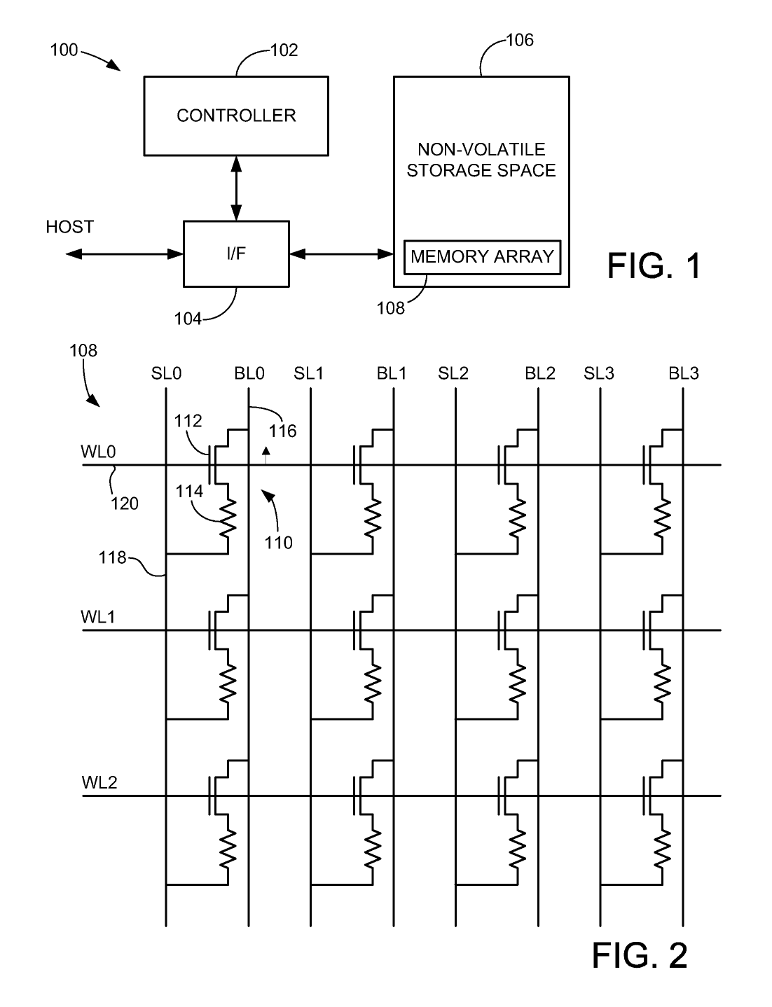

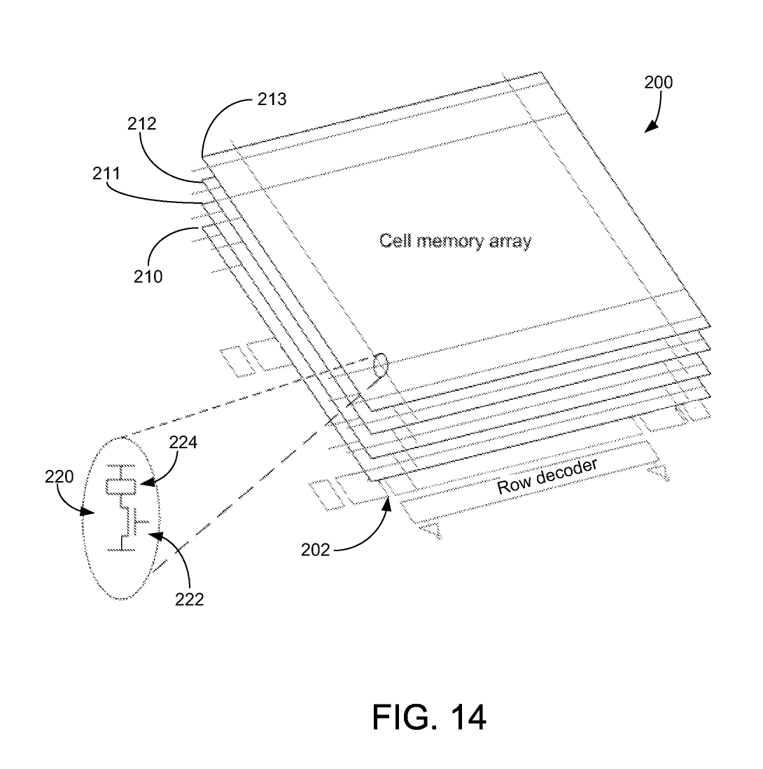

The present disclosure is generally directed to an apparatus characterized as a multi-wafer structure with embedded (bottom side) control lines, and an associated method for making the same. The embedded control lines provide electrical interconnection with vertically stacked semiconductor elements within the multi-wafer structure. FIG. 1 to FIG. 13 illustrate the formation of the base circuitry layer and the first memory array layer. FIG. 14 to FIG. ______ illustrate stacking and forming memory array layers onto the base circuitry layer and the first memory array layer to form the 3D memory array of the present disclosure.

In various embodiments, an acceptor wafer is formed that incorporates various control circuitry, and a donor wafer is formed that incorporates a matrix from which individual channel based switching devices (e.g., vertical pillar transistors) are subsequently formed.

The acceptor wafer and the donor wafer are each provided with a metal layer on a respective facing surface. The acceptor and donor wafers are attached to form the multi-wafer structure, and during this attachment process the respective metal layers are brought together to form a single combined metal layer that is embedded within the multi-wafer structure. The combined metal layer is transformed during subsequent processing into individual embedded bottom side control lines (e.g., embedded source lines).

FIG. 1 provides an illustrative device environment in which such processing can be advantageously utilized. In FIG. 1, a data storage device 100 employs semiconductor memory to store data supplied by a host. In some embodiments, the device 100 is characterized as a non-volatile solid state drive (SSD), although such is not limiting. In many embodiments, the device 100 is characterized as a volatile dynamic random access memory (DRAM), non-volatile resistive random access memory (RRAM), and non-volatile spin-torque transfer random access memory (STRAM).

A programmable controller 102 provides top level control of the device 100 during operation. An interface circuit (I/F) 104 communicates with the host and transfers data to be stored in a semiconductor memory 106.

The semiconductor memory 106 is characterized as a non-volatile storage space formed from one or more arrays 108 of non-volatile memory cells (e.g., RRAM or STRAM. In other embodiments, the memory 106 can take the form of a volatile memory space such as a DRAM cache. Additional hierarchical memory storage layers can be provided such as a downstream non-volatile main storage (e.g., a magnetic disc, etc.).

FIG. 2 is a schematic representation of a portion of the non-volatile array 108 of FIG. 1. The array 108 is formed from a number of memory cells 110 arranged into rows and columns. While only three (3) rows and four (4) columns are shown in FIG. 2, it will be appreciated that any numbers of rows and columns of the cells 110 can be provided.

Each cell 110 in the array 108 includes a switching device 112 connected in series with a resistive memory element 114. In some embodiments, the switching devices 112 are characterized as n-channel MOSFETs (transistors), and the memory elements 114 are programmable resistive sense elements such as but not limited to resistive random access memory (RRAM) elements, spin-torque transfer random access memory (STRAM) elements or programmable metallization cells (PMCs).

A number of bit lines 116 denoted as BL0-BL3 interconnect a first end (“top side”) of each of the cells along each column. Source lines 118 denoted as SL0-SL3 interconnect an opposing, second end (“bottom side”) of each of the cells along each column. Word lines 120 denoted as WL0-WL2 interconnect the gate regions of the MOSFETs 112 along each row. It will be appreciated that other arrangements and interconnection schemes can be employed, so that the schematic representation of FIG. 2 is merely illustrative and not limiting.

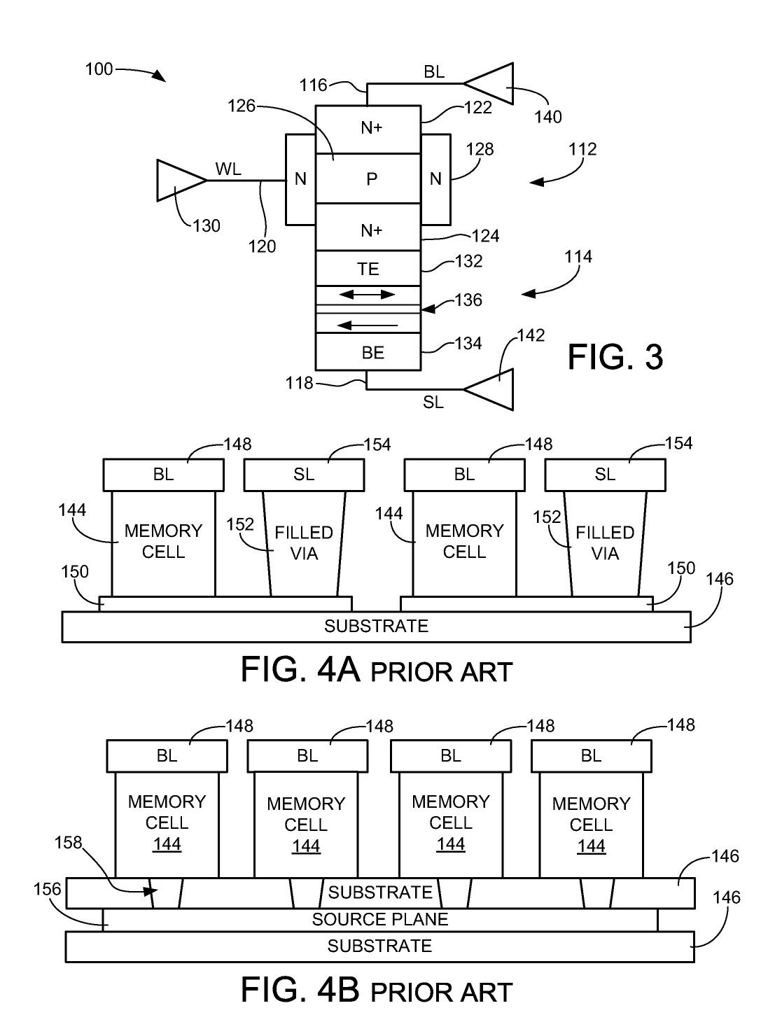

FIG. 3 is a layer representation of a selected memory cell 110 from FIG. 2 in accordance with some embodiments. The transistor 112 is formed from respective N+ doped regions 122, 124 separated by a vertically extending P doped channel region 126. An N doped control gate 128 surrounds the channel region 126 (a gate oxide layer, not shown here, separates the N doped control gate 128 from the N+ doped regions 122, 124 and P doped channel region 126). Application of a suitable bias voltage from a word line (WL) driver 130 will place the transistor 112 in a forward biased (conductive) state, allowing currents to pass through the memory cell 110 across the drain-source junction.

The memory element 114 is characterized in FIG. 3 as an RRAM or STRAM element and includes top and bottom electrodes (TE, BE) 132, 134 separated by a magnetic tunnel junction 136. The magnetic tunnel junction 136 includes a magnetic free layer (double arrow layer) and a magnetic pinned layer (single arrow layer) separated by a tunnel barrier layer. The STRAM 136 cell is programmed by passing a spin polarized write current through the STRAM 136 cell in a first or second direction.

To program the memory cell 110 to a desired state, the WL driver 130 will assert the WL 120 and respective BL and SL drivers 140, 142 will direct current through the memory element 114 in the appropriate direction and at the appropriate voltage and current magnitudes. The programmed state of the element 114 can be subsequently read by asserting the WL 120, passing a smaller read bias current through the memory cell 110 such as from BL driver 140 to SL driver 142, and comparing the resulting voltage on the BL 116 to a reference voltage using a separate sense amplifier (not shown).

The stacked nature of the memory cell 110 in FIG. 3 provides a number of advantages. The relatively small areal extent of the memory cell allows arrays such as in FIG. 2 to achieve relatively high areal densities. However, a limitation with stacked memory cells such as set forth in FIG. 3 relates to establishing access to the bottom side of the memory cell; that is, it has been found difficult to establish an electrical interconnection such as that shown in FIG. 3 between the SL driver 142 and the BE 134.

One prior art solution uses filled via structures such as depicted in FIG. 4A. In this approach, individual stacked memory cells 144 are supported above a base substrate 146, and bit lines 148 are connected to the tops of the memory cells 144. Bottom-side connections can be made using embedded conductive pads 150 and vias 152 that are disposed adjacent the memory cells 144 and filled with a conductive material. Source lines 154 are connected to the top sides of the vias 152, so that the source lines run adjacent the bit lines 148 across the top of the array.

While operable, it can be appreciated that the approach in FIG. 4A reduces areal density of the array due to the additional space required for the filled vias 152. The approach in FIG. 4A may further require enhanced manufacturing complexities and costs to form the vias and the conductive pad interconnections.

Another prior art solution that has been employed with stacked cells is the use of a common source plane (SP), such as depicted at 156 in FIG. 4B. The source plane 156 extends below the respective stacked memory cells 144 so that all of the memory cells in the array are interconnected to the source plane, such as through vias 158 that extend through an upper oxide substrate 146. As before, individual rows (or columns) of the memory cells are interconnected via separate bit lines 148.

While operable, limitations with FIG. 4B include the enhanced processing and cost to form the metallization of the entire source plane, as well as limitations during operation in that currents generally cannot be passed through two or more cells concurrently in opposing directions. Other prior art solutions include additional interconnection layers and contact layers to accommodate the bottom side interconnections for the stacked memory cells.

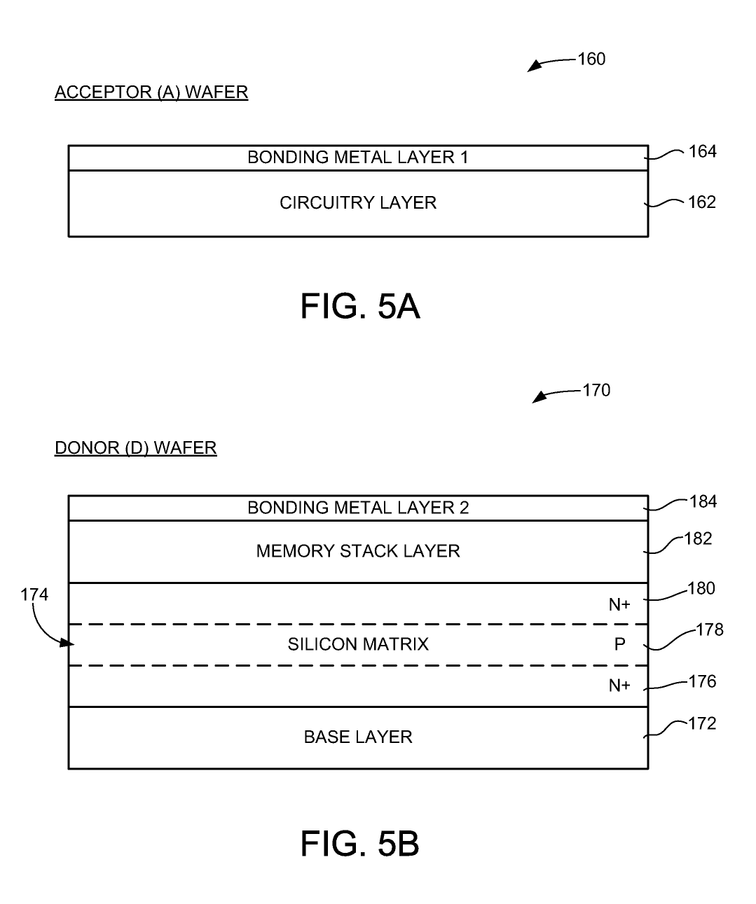

Accordingly, various embodiments of the present invention are generally directed to a manufacturing process that efficiently and easily forms bottom-side control lines (e.g., source lines) for an array of vertically stacked memory cells. To illustrate such processing, reference is first made to FIGS. 5A and 5B which respectively show an acceptor (A) wafer 160 and a donor (D) wafer 170. In some embodiments, the wafers 160, 170 are silicon based substrates which are separately formed with a number of initial, respective features.

The acceptor wafer 160 includes a circuit layer 162 in which various control circuits, including CMOS circuitry, are formed during prior processing. This circuitry may include the various drivers shown in FIG. 3, as well as other control circuitry used in conjunction with the cells 110. The circuit layer 162 may also include contacts for the various vertical transistors. A first conductive metal layer 164 is formed on a top facing surface of the circuit layer 162. The metal layer 164 can be formed of any suitable metals or metal alloys. As desired, the metal layer can include multiple layers of conductive and dielectric materials, and provides a relatively low resistance per unit length.

The donor wafer 170 includes a number of layers including a base layer 172, which may be a bulk oxide. A doped silicon matrix 174 is formed in the base layer, and includes regions 176, 178 and 180 of respective NPN doping levels to ultimately form the respective drain, source and channel regions 122, 124 and 126 in FIG. 3. The doped regions can be formed using ion implantation or other techniques.

A memory element layer 182 is provided on the silicon matrix 174, and includes a number of layers to form a memory element such as the layers 132, 134 and 136 in FIG. 3. As will be appreciated, the particular format of the memory layer 182 will depend on the style of memory element 114 to be used in the completed memory cells 110. A second conductive metal layer 184 is formed on a top facing surface of the memory layer 182. The material composition of the second metal layer 184 may be the same, or different from, the first metal layer 164.

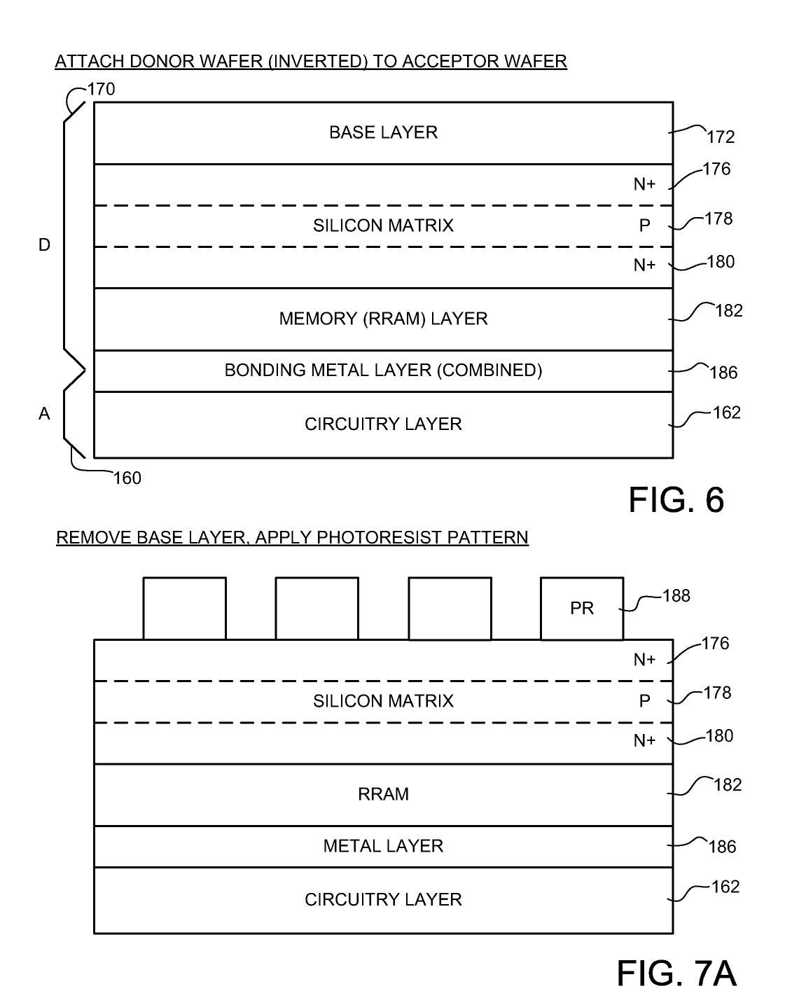

The respective wafers 160, 170 are mated as shown in FIG. 6 to form a multi-wafer structure. The donor wafer 170 is inverted relative to the acceptor wafer 160 and the first and second metal layers 164, 184 are bonded together to provide a combined metal layer 186. Any number of suitable bonding processes can be utilized, including reflow heating. Additional materials can be introduced to establish the metalized layer 186 interconnection during the bonding process.

As will become apparent from the following discussion, the individual control (source lines) are eventually formed from this metal layer 186, so the metal layer can be characterized as a planar extent of conductive material with a substantially uniform thickness and overall length and width dimensions substantially corresponding to the overall length and width dimensions of the multi-wafer structure. In this way, the finished control lines will fully extend across the array in parallel, spaced apart fashion in the desired direction (e.g., in the row direction or the column direction, as required).

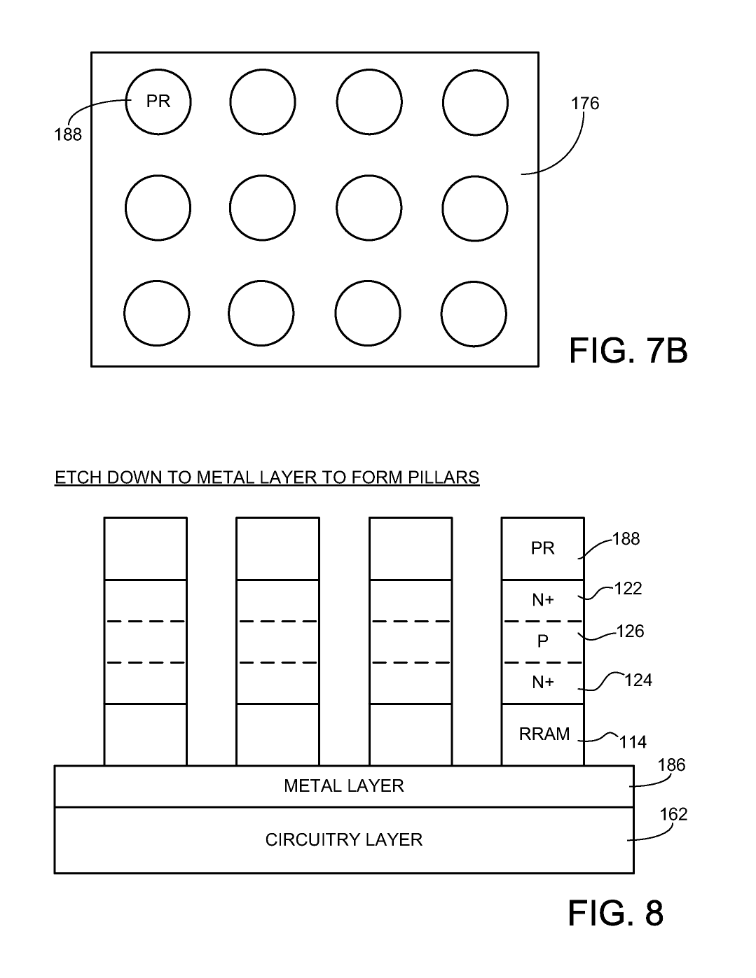

The base oxide layer 172 is removed and localized areas (dots) of photoresist (PR) 188 are applied to the top of the silicon matrix, as shown in FIGS. 7A-7B. The dots of PR 188 are circular in shape in the illustrated embodiment to provide a cylindrical cross-sectional shape for the cells, although other cross-sectional shapes can be alternatively provided. An etching process is next carried as set forth by FIG. 8, which removes all of the material not covered by the dots of PR 188 down to the metal layer 186. At the end of this etching process, spaced apart pillars, or vertical stacks, of layers will be left which correspond to the individual memory cells as set forth in FIG. 3.

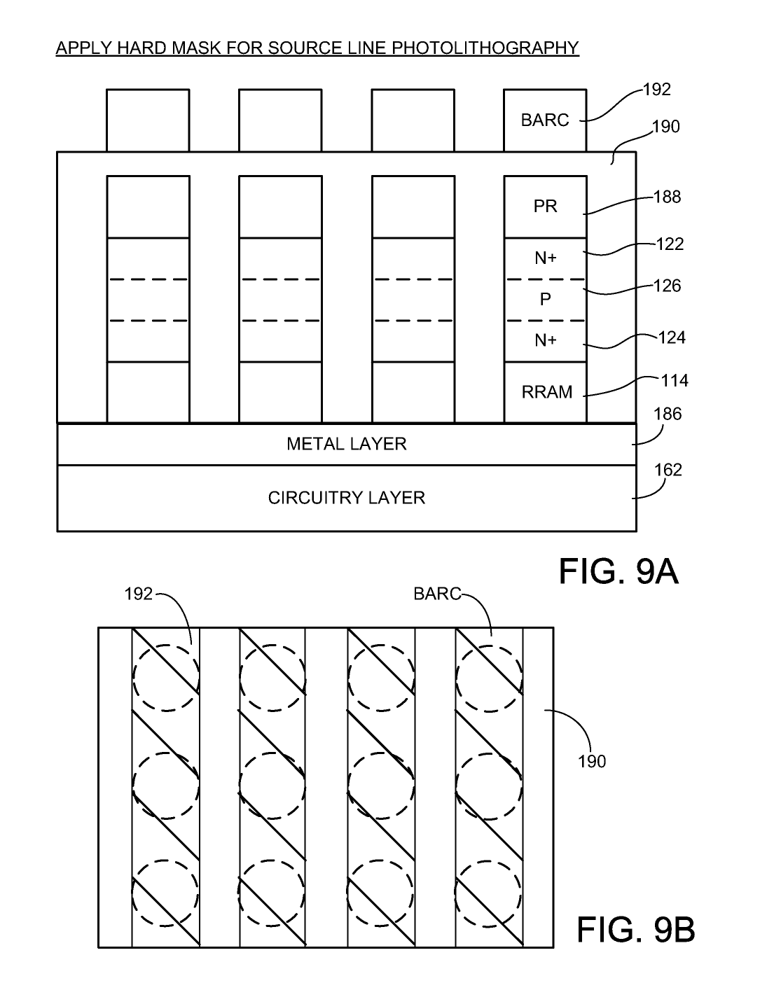

A hard mask is applied as shown in FIGS. 9A-9B to form the individual control (source) lines. Organic material 190 is deposited between the layers and, as desired, a bottom antireflective coating (BARC) or other photolithography masking material 192 can be applied to aid the process. The masking material 192 extends across the top of the organic material 190 over the respective stacks as depicted in cross-hatched fashion in FIG. 9B.

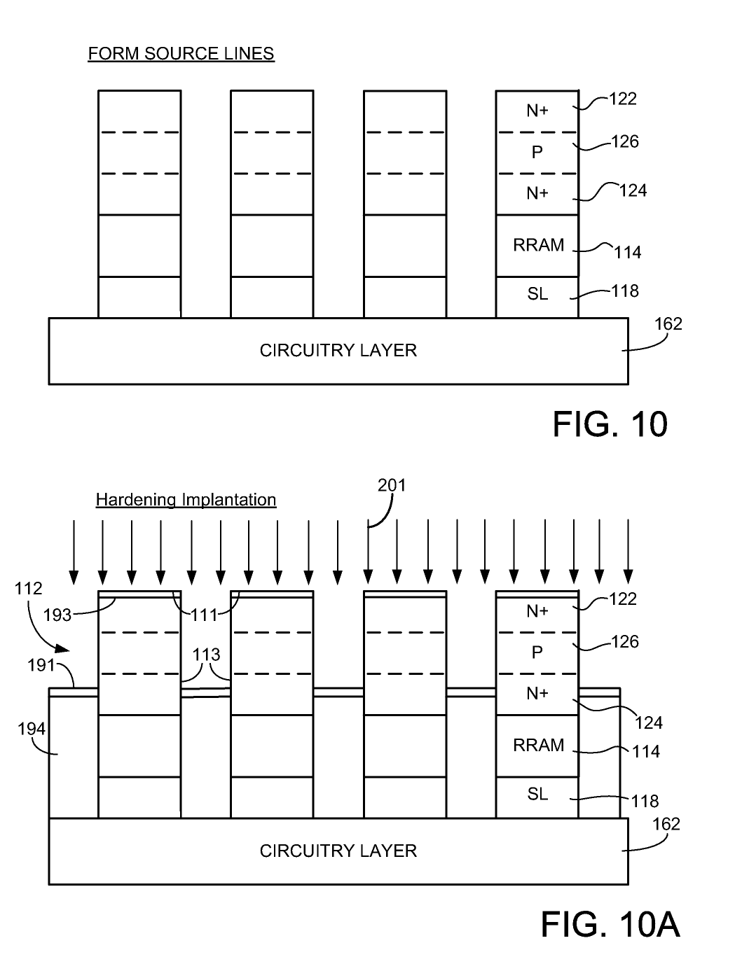

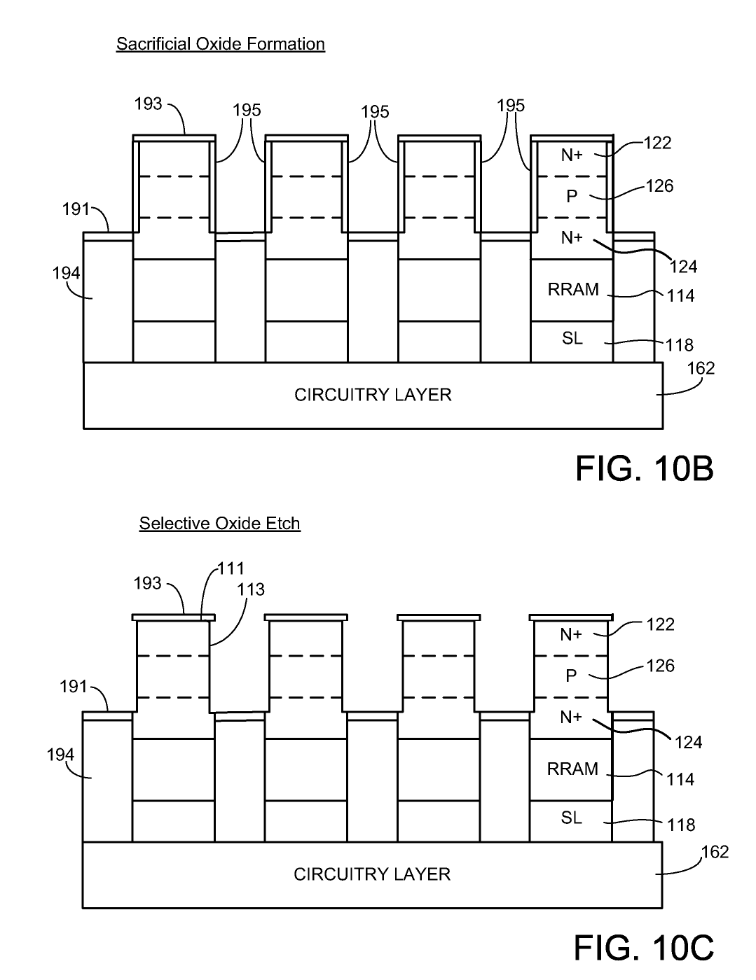

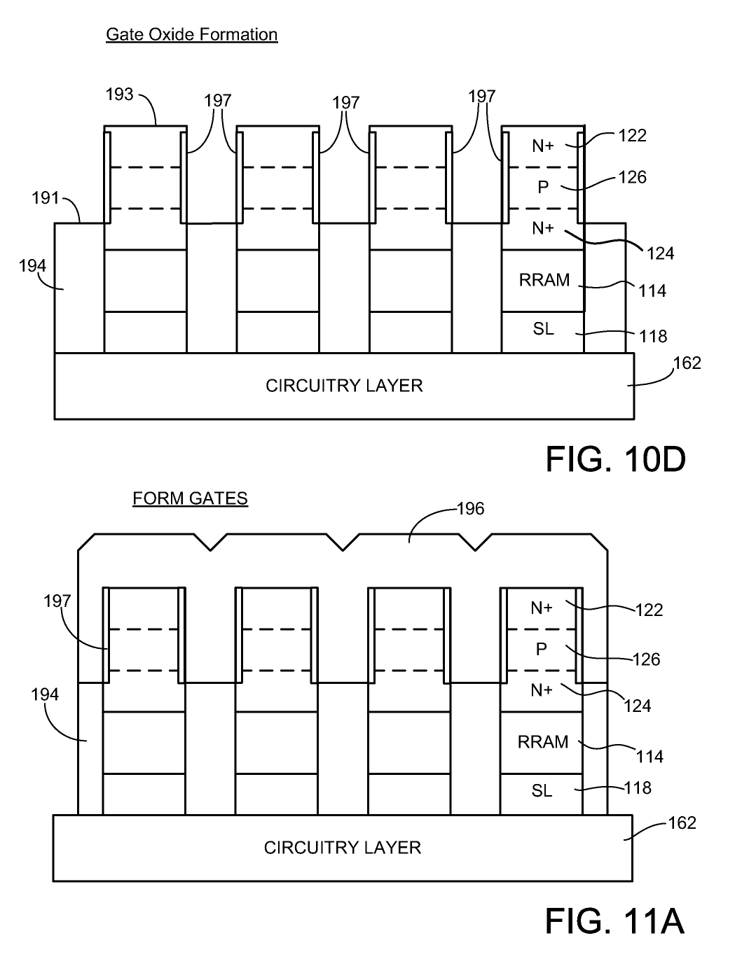

An etching process is carried out in FIG. 10 to form the source lines 118. The etching removes the organic material and portions of the conductive layer 186 down to the underlying circuitry layer 162, so that the resulting source lines run under the columns of stacks as shown in FIG. 9B. The photoresist PR 188, organic material 190 and masking material 192 on the top of each stack are also removed at this point.

FIG. 10A illustrates a side elevation view of a hardening implantation step. FIG. 10B illustrates a side elevation view of a sacrificial oxide formation step. FIG. 10C illustrates a side elevation view of a selective oxide etch step. FIG. 10D illustrates a side elevation view of a gate oxide formation step. These steps allow the preferential rounding of the vertical pillar transistor side surfaces while maintaining a sharp edge with the vertical pillar top surface. These features improve the performance of the vertical pillar transistor.

An underlying dielectric material, such as an oxide 194, is deposited around the bases of the stacks or plurality of pillar structures up to the desired height. The plurality of pillar structures extends orthogonally from the semiconductor wafer or circuitry layer 162.

Each pillar structure will form a vertical pillar transistor 112 having a top surface 111 and a side surface 113 orthogonal to the top surface. The top surface 111 is generally planar and parallel with the major surface of the semiconductor wafer or circuitry layer 162. In many embodiments the cross-sectional or top view shape of the pillar structure includes sharp angles where the sides surfaces of the pillar structure intersect. These sharp angles can decrease the performance of the formed vertical pillar transistor 112. Thus rounding these sharp edges or corners is desired.

One illustrative method of rounding these sharp edges or corners of the side surfaces of the pillar structure is to implant a hardening species into the vertical pillar transistor top surface and not in the vertical pillar transistor side surface(s). The hardening implant step implants a particular ion (e.g., nitrogen) into the semiconductor material surface (e.g., silicon) so that when that implanted semiconductor material surface is oxidized, it forms an oxide that includes the implanted ion (e.g., silicon oxynitride). The remaining non-implanted surfaces will form a different oxide species upon the oxidation step. Then the two different oxide layers can be preferentially removed utilizing an appropriately oxide selective removal or etching step.

As illustrated in FIG. 10A, a hardening implantation 201 directs an implantation ion into the vertical pillar top surfaces 111 and the parallel exposed oxide 194 surfaces that was deposited up to a desired height of the vertical pillars. The implantation step forms ion (e.g., nitrogen) implanted surfaces 193 and 191 that will form a first oxide layer (e.g., silicon oxynitride) upon oxidation.

FIG. 10B illustrates the formation of the sacrificial oxide formation. The vertical pillar transistor is oxidized to form a top surface oxide material layer 193 and a side surface oxide material layer 195. The top surfaces oxide material layer 193 is different than the side surface oxide material layer 195 due to the hardening implantation step.

FIG. 10C illustrates a side elevation view of a selective oxide etch step. The selective etch step preferentially removes the side surface oxide layer 195 to form a vertical pillar transistor having rounded side surfaces. For example, if the hardening implantation ion is nitrogen, the oxidation step will form a silicon oxynitride layer 193, 191 on the top surfaces 111 and a silicon oxide layer 195 on the sides surfaces 113. The silicon oxide layer 195 on the sides surfaces 113 can be selectively etched relative to the silicon oxynitride layer 193, 191 on the top surfaces 111. The oxide formation and selective etching of the sides surfaces 113 functions to round out the side surfaces 113 of the vertical pillar while the corner or edge where the top surface 111 meets the side surface 113 remains a sharp or non-rounded intersection of the two surfaces 111 and 113.

FIG. 10D illustrates a side elevation view of a gate oxide formation step. A gate oxide layer 197 can then be formed on the rounded side surfaces 113 of the vertical pillar. Forming the gate oxide layer 197 can further enhance the rounding of the side surfaces 113 of the vertical pillar forming a rounded gate oxide surfaces of the vertical pillar structure.

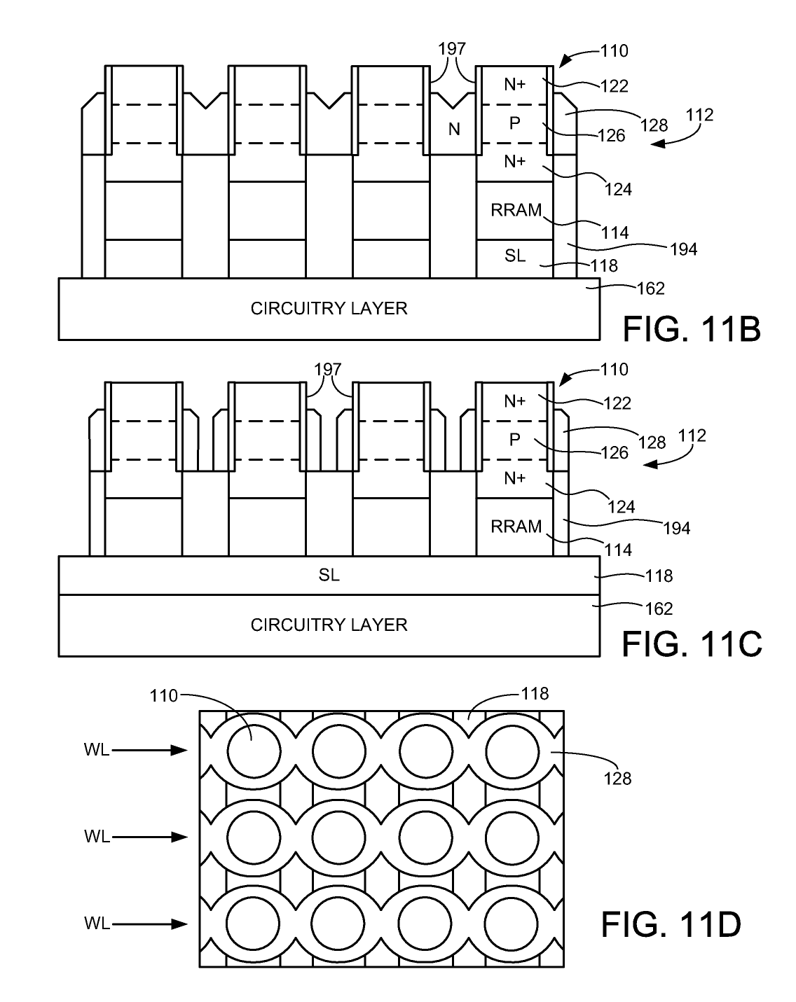

FIGS. 11A-11D show a sequence in which gate structures are formed on the rounded gate oxide surfaces of the vertical pillar structure. An appropriate semiconductor gate material 196 such as silicon is deposited on top of the oxide 194 to fully enclose the stacks or vertical pillar sturctures, as shown in FIG. 11A. The semiconductor material can be doped via ion implantation at this time. A suitable masking and etching process removes the semiconductor material down to form the gate structures as generally depicted at 128 in FIG. 3. FIG. 11B shows a row of the cells; FIG. 11C shows a column of the cells; and FIG. 11D shows a top plan representation of the cells. As can be seen from these drawings, the gate structures 128 are interconnected along each row to form the aforementioned word lines 120, and the gate structures of each selected row are electrically isolated from those of the adjacent rows.

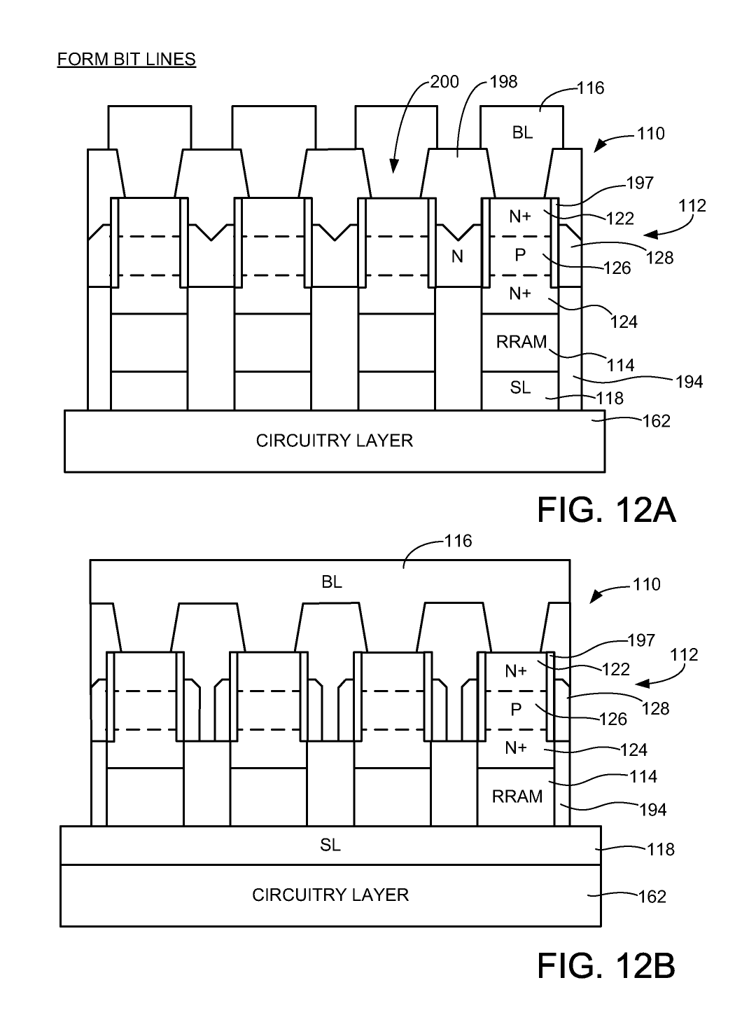

Top side bit lines (116 in FIGS. 2-3) are next formed in FIGS. 12A-12B. In some embodiments, a layer of oxide 198 or other dielectric is deposited onto the memory cells as shown in FIG. 12A. This oxide 198 fills the areas between adjacent gate structures 126 and forms a uniformly thick layer above the top elevation of the cells. Vias 200 are formed in this oxide layer and filled with conductive material using a physical vapor deposition or other suitable process.

The deposited material forms a layer of uniform thickness that covers the length and width dimensions of the overall array. Suitable masking and etching processing (not separately depicted) removes portions of this material to form the parallel, spaced apart bit lines 116 as shown. FIG. 12A shows the completed memory cells 110 along a selected row, and FIG. 12B shows the completed memory cells along a selected column. It will be noted that in this embodiment the bit lines 116 and source lines 118 are parallel and orthogonal to the word lines 120, corresponding to the schematic depiction of FIG. 2. The processing disclosed herein can provide other arrangements and orientations of these respective control lines as required.

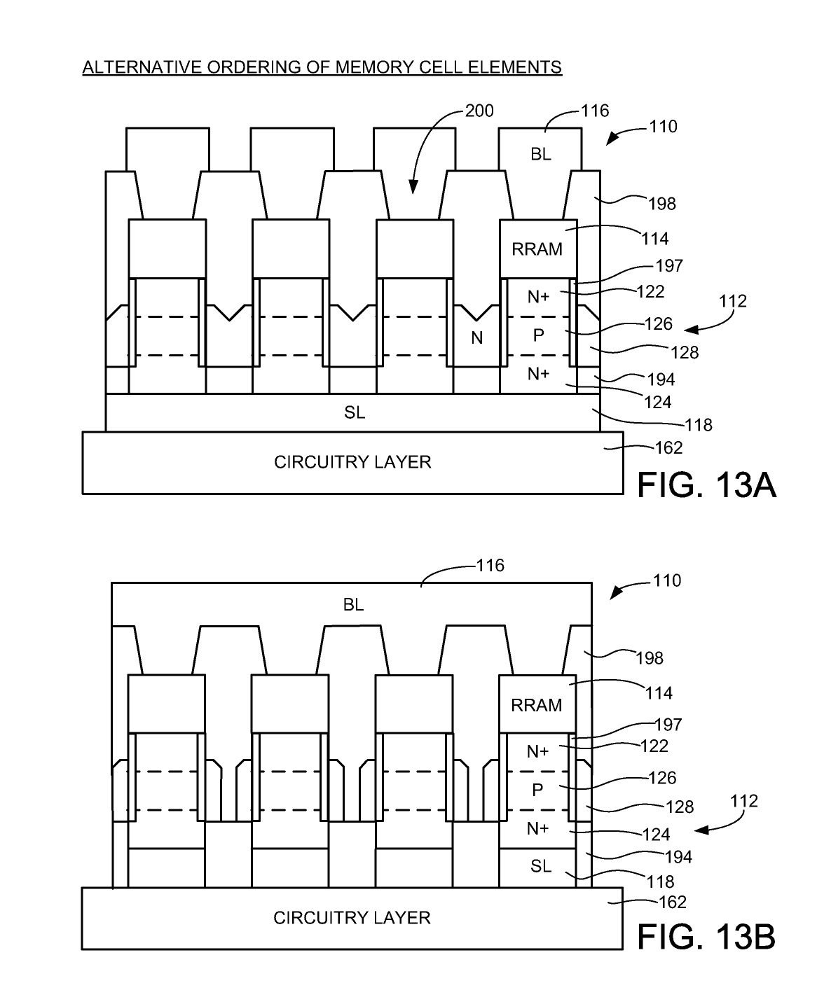

FIGS. 13A and 13B show an alternative operation of the foregoing process to provide an array with memory cells 110A. As before, FIG. 13A shows a row of cells and FIG. 13B shows a column of cells. The memory cells 110A are similar to the memory cells 110 except that the memory element 114 is located above the switching device 112 in FIGS. 13A-13B. These figures also show an alternative orientation of the source lines 116, which are orthogonal to the bit lines 118 and parallel with the word lines 120. That is, both the source lines 118 and the word lines 120 are connected along each row in the array.

FIG. 14 is an exploded perspective schematic diagram of an illustrative 3D memory array 200. The 3D memory array 200 includes a base circuitry layer 202 and a plurality of memory array layers 210, 211, 212, and 213 stacked sequentially to form the memory array 200. Each memory array layer layers 210, 211, 212, and 213 is electrically coupled to the base circuitry layer 202. Each memory array layer 210, 211, 212, and 213 includes a plurality of memory units 220 including a vertical pillar transistor 222 electrically coupled to a memory cell 224 (as described above). Each memory unit 220 is located at the intersection of row and column lines forming cross point architecture.

The memory cells 224 can be STRAM or RRAM memory cells, as described above. The plurality of memory array layers 210, 211, 212, and 213 can be stacked in a co-planar arrangement where each of the layers are electrically isolated form each other. Each of the plurality of memory array layers 210, 211, 212, and 213 are electrically coupled to the base circuitry layer 202 and can be operated by the base circuitry layer 202. The vertical pillar transistor 222 of each memory unit has a drain, source and channel regions that are vertically stacked on top of each other and extending away from the base circuitry layer 202, as described above and illustrated in FIG. 5A to FIG. 13B.

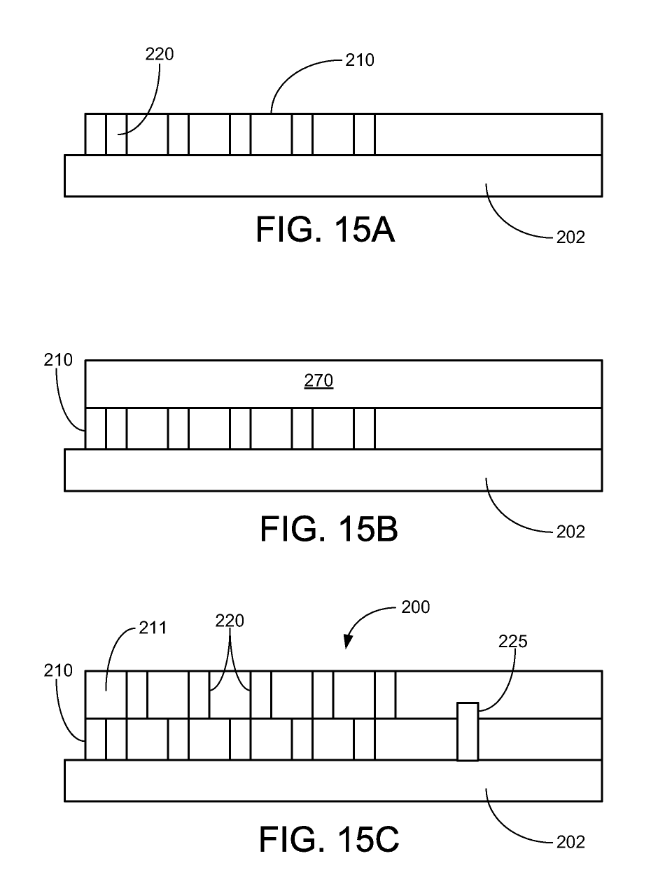

FIG. 15A to FIG. 15C are schematic diagram side elevation views of method of forming an illustrative 3D memory array. The method includes forming a first memory array layer 210 on a base circuitry layer 202 as described above and illustrated in FIG. 5A to FIG. 13B. The first memory array layer 210 is electrically coupled to the base circuitry layer 202. The first memory array layer 210 includes a plurality of memory units having a vertical pillar transistor electrically coupled to a STRAM or RRAM memory cell.

FIG. 15 B illustrates disposing a semiconductor layer 270 on the first memory array layer 210. The semiconductor layer 270 is a element similar to the donor wafer (described above) and includes a number of layers that can form the vertical pillar transistor and the memory cell, as described above.

FIG. 15C illustrates a second memory array layer 211 formed from the semiconductor layer 270. The second memory array layer 211 is electrically coupled to the base circuitry layer 202 by a contact 225. The second memory array layer 211 includes a plurality of memory units 220 having a vertical pillar transistor electrically coupled to a STRAM or RRAM memory cell.

A third and fourth memory array layers 212, 213 can be sequentially formed as described above and electrically coupled to the base circuitry layer 202 by a contact. The memory array layers 210, 211, 212, 213 are electrically isolated from each other and each layer is controlled independently by the base circuitry layer 202. The 3D array can be formed of any number of 2 or more layers by repeating the method described and illustrated in FIG. 15B and FIG. 15C.

It will now be appreciated that the various embodiments as presented herein provide a number of advantages over the prior art. Spaced apart bottom side control lines can be easily and efficiently formed during manufacturing, eliminating the need for additional interconnections and conductive layers. Unlike top side interconnection techniques, the present process allows the source lines to run independently of the bit lines. Enhanced data densities can be achieved and multiple concurrent access operations can be carried out on different parts of the array, as desired.

Thus, embodiments of the 3D MEMORY ARRAY WITH VERTICAL TRANSISTOR are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. A memory array comprising:
a base circuitry layer;
a first memory array layer disposed on the base circuitry layer and electrically coupled to the base circuitry layer, the first memory array layer comprising a plurality of memory units, each memory unit comprising a vertical pillar transistor electrically coupled to a memory cell; and
a second memory array layer disposed on the first memory array layer and electrically coupled to the base circuitry layer, the second memory array layer comprising a plurality of memory units, each memory unit comprising a vertical pillar transistor electrically coupled to a memory cell.

2. The memory array according to claim 1 wherein the memory cells comprise STRAM memory cells.

3. The memory array according to claim 1 wherein the first memory array layer separates at least a portion of the second memory array layer from the base circuitry layer.

4. The memory array according to claim 1 further comprising three or more memory array layers stacked sequentially to form the memory array and wherein each memory array layer is electrically coupled to the base circuitry layer.

5. The memory array according to claim 1 wherein the first memory array layer is electrically isolated from the second memory array layer.

6. The memory array according to claim 1 wherein the first memory array layer and the second memory array layer includes a plurality of rows and columns of memory units.

7. The memory array according to claim 1 wherein the vertical pillar transistor of each memory unit has a drain, source and channel regions that are vertically stacked on top of each other and extending away from the base circuitry layer.

8. The memory array according to claim 4 wherein the base circuitry layer controls the memory units in all of the memory array layers.

9. A memory array comprising:
a base circuitry layer;
a plurality of memory array layers stacked sequentially to form the memory array and wherein each memory array layer is electrically coupled to the base circuitry layer, wherein each memory array layer comprises a plurality of memory units, each memory unit comprising a vertical pillar transistor electrically coupled to a memory cell.

10. The memory array according to claim 9 wherein the memory cells comprise STRAM memory cells.

11. The memory array according to claim 9 wherein the memory cells comprise RRAM memory cells.

12. The memory array according to claim 9 wherein the memory array layers are electrically isolated from each other.

13. The memory array according to claim 9 wherein the memory array layers include a plurality of rows and columns of memory units.

14. The memory array according to claim 9 wherein the vertical pillar transistor of each memory unit has a drain, source and channel regions that are vertically stacked on top of each other and extending away from the base circuitry layer.

15. The memory array according to claim 9 wherein the base circuitry layer controls the memory units in all of the memory array layers.

16. A method of forming a memory array comprising:
forming a first memory array layer on a base circuitry layer, the first memory array layer is electrically coupled to the base circuitry layer, wherein the first memory array layer comprises a plurality of memory units, each memory unit comprising a vertical pillar transistor electrically coupled to a memory cell;
disposing a semiconductor layer on the first memory array layer;
forming a second memory array layer from the semiconductor layer; the second memory array layer is electrically coupled to the base circuitry layer, wherein the second memory array layer comprises a plurality of memory units, each memory unit comprising a vertical pillar transistor electrically coupled to a memory cell.

17. The method according to claim 16 further comprising forming a third memory array layer on the second memory array layer, the third memory array layer is electrically coupled to the base circuitry layer, wherein the second memory array layer comprises a plurality of memory units, each memory unit comprising a vertical pillar transistor electrically coupled to a STRAM memory cell.

18. The method according to claim 16 wherein the first and second memory array layers are electrically isolated from each other.

19. The method according to claim 16 further comprising controlling the memory units in the first and second memory array layers by the base circuitry layer.

20. The method according to claim 16 wherein the vertical pillar transistor of each memory unit has a drain, source and channel regions that are vertically stacked on top of each other and extending away from the base circuitry layer.
